(19) United States
(12) Patent Application Publication
(10) Pub. No.: US 2011/0007568 A1
(43) Pub. Date: Jan. 13, 2011

(54) NAND TYPE ROM

(75) Inventors: Meng-Fan Chang, Taichung City (TW); Chih-Wei Liang, Fusing Township (TW); Chih-Chyuang Chiang, Cyonglin Township (TW)

Correspondence Address: WPAT, PC;INTELLECTUAL PROPERTY ATTORNEYS, 2030 MAIN STREET, SUITE 1300, IRVINE, CA, 92614, US

(73) Assignee: NATIONAL TSING HUA UNIVERSITY, Hsin-Chu (TW)

(21) Appl. No.: 12/500,236

(22) Filed: Jul. 9, 2009

(51) Int. Cl. G11C 16/04

(52) U.S. Cl. 365/185.17

(57) ABSTRACT

The invention discloses a NAND type ROM. The NAND type ROM comprises a plurality of bit lines, a plurality of word lines, a first source line, a second source line, and a plurality of NAND strings. The bit lines comprise a plurality of upper bit lines, first lower and second lower bit lines. The first lower and second lower bit lines are alternately arranged in parallel, and the plurality of word lines are vertically arranged to each bit lines. The first and second source line are respectively connected to the plurality of first and second lower bit lines. The plurality of NAND strings comprise a plurality of first and second NAND strings. The first NAND strings are connected to the upper bit lines, word lines, and first lower bit lines. The second NAND strings are connected to the upper bit lines, word lines, and second lower bit lines.

### BACKGROUND OF THE INVENTION

(a) Field of the Invention

The present invention relates a NAND type ROM, and more particularly to a NAND type ROM that solves a crosstalk problem by a first source line and a second source line which are alternately arranged.

(b) Description of the Prior Art

In designing read-only memories (ROMs), code-dependent crosstalk leads to problems such as lower operating speeds and read errors. Such crosstalk is caused because bit lines are adjacently disposed and thus the parasitic capacitances effect occurs between every two adjacent bit lines. As illustrated in FIG. 1, in which a schematic view of a NAND type ROM array of the prior art is illustrated. In this figure, the ROM array comprises a plurality of NAND strings 11 and a plurality of bit lines (BL) 12. The bit lines 12 are adjacently disposed, so the parasitic capacitances 13 are arisen between every two adjacent bit lines.

Referring to FIG. 2, in which a schematic view of a NAND string of the prior art is shown. In a general NAND type metal-programming ROM, whether the stored data is 0 (0-cell) or 1 (1-cell) is determined by the presence of a metal layer 21 in the source and drain of a transistor. If the metal layer 21 is present, the stored data is 0. If the metal layer 21 is not presented, the stored data is 1.

Referring to FIG. 3, in which an oscillogram of a NAND type metal-programming ROM during the read operation is shown. Also referring to FIG. 2, all the word lines WL[0]-WL[15] are pre-charged to V_{DD} before the read operation. When a row is driven by a selected word line 31 and a select gate 32 and when the data read by a bit line 33 is 0-cell, the voltage would be pulled down. When a row is driven by a selected word line 31 and a select gate 32 and when the data read by a bit line 33 is 1-cell, the voltage is not pulled down.

Referring to FIG. 4, in which a schematic view of a NAND type ROM of the prior art is shown. Referring to FIG. 5, in which an oscillogram of operating a NAND type ROM of the prior art is shown. All the word lines are pre-charged to V_{DD} before the reading operation. When the word line WL[10] is driven and the logic state of the transistor 411 is read by the bit line BL[0] and the bit line BL[2], the transistor 411 has a metal layer between the source and drain thereof. The read logic state of the transistor is 0 (0-cell) so that the voltage is pulled down. Due to a coupling noise arisen by the parasitic capacitances of the adjacent bit lines BL[0] and BL[2], the voltage of the transistor 412 on the bit line BL[1] should be a constant value but the voltage drop results the erroneous read data. The more 0-cells in the code pattern, the current through the NAND string is greater and the resulted crosstalk is more significant. Furthermore, a greater voltage swing at the bit lines causes a more significant crosstalk.

### SUMMARY OF THE INVENTION

In light of the above problems of the prior art, it is an object of the present invention to provide a NAND type ROM so as to solve the voltage drop that occurs between the adjacent bit lines because of capacitance coupling.

According to an object of the present invention, there is provided a NAND type ROM comprising a plurality of bit lines, a plurality of word lines, a first source line, a second source line, and a plurality of NAND strings. The plurality of bit lines comprise a plurality of upper bit lines, a plurality of first lower bit lines, and a plurality of second lower bit lines. The plurality of first lower bit lines and the plurality of second lower bit lines are alternately arranged in parallel, and the plurality of word lines are vertically arranged to each bit lines. The first source line is connected to the plurality of first lower bit lines, and the second source line is connected to the plurality of second lower bit lines. The plurality of NAND strings comprise a plurality of first NAND strings and a plurality of second NAND strings. The plurality of first NAND strings are connected to the plurality of upper bit lines, the plurality of word lines, and the plurality of first lower bit lines. The plurality of second NAND strings are connected to the plurality of upper bit lines, the plurality of word lines, and the plurality of second lower bit lines.

The NAND type ROM further comprises a select gate line, and the plurality of NAND strings are driven by the plurality of word lines and the select gate line.

Each NAND strings is formed by cascading a plurality of transistors.

The gate of each transistors is electrically connected to each word lines.

When the plurality of first NAND strings are read, the operating voltage of the first source line is a low-level voltage and the operating voltage of the second source line is a high-level voltage.

When the plurality of second NAND strings are read, the operating voltage of the second source line is a low-level voltage and the operating voltage of the first source line is a high-level voltage.

As stated above, the present invention may provide one or more of the following advantages:

(1) The NAND type ROM may solve the crosstalk problem by means of adopting the first source line and the second source line which are alternately arranged.

(2) The NAND type ROM allows no voltage drop caused by capacitance coupling to occur between the adjacent bit lines and the reduction of read errors such that the NAND type ROM has full code-coverage and an increased reading speed.

### BRIEF DESCRIPTION OF THE DRAWINGS

FIG. 1 is a schematic view of a NAND type ROM array of the prior art;

FIG. 2 is a schematic view of a NAND string of the prior art;

FIG. 3 is an oscillogram of a NAND type metal-programming ROM of the prior art during the read operation;

FIG. 4 is a schematic view of a NAND type ROM of the prior art;

FIG. 5 is an oscillogram of a NAND type ROM of the prior art during the operation;

FIG. 6 is a schematic view of a NAND type ROM of the present invention; and

FIGS. 7 and 8 are oscillograms of a NAND type ROM of the present invention.

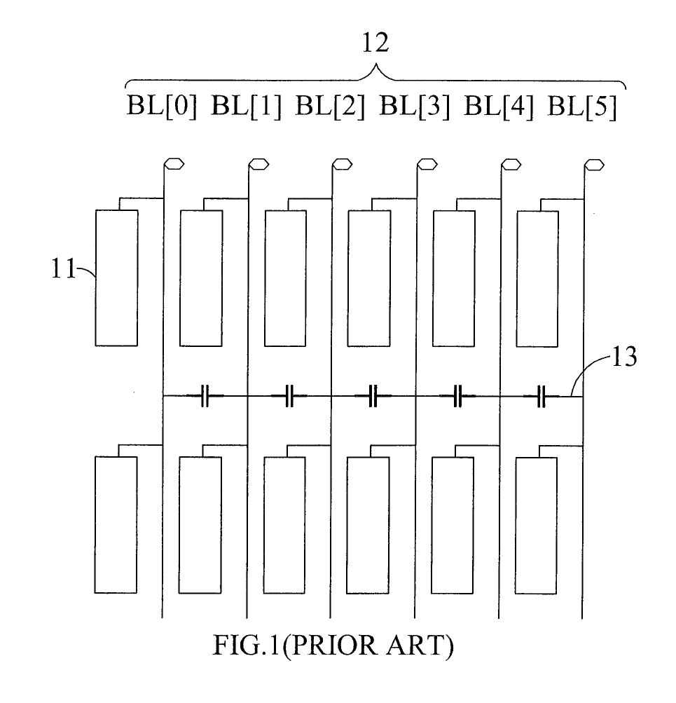

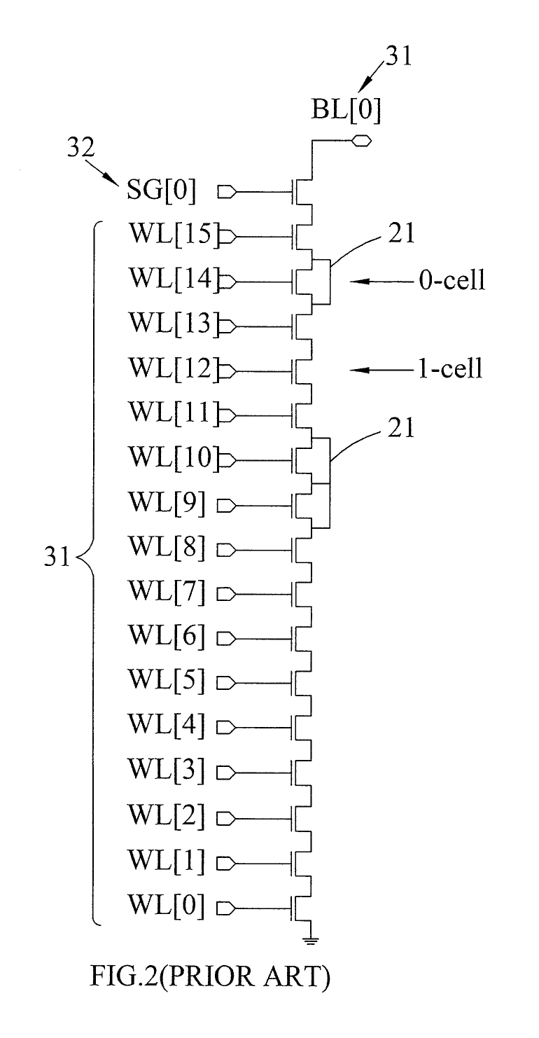

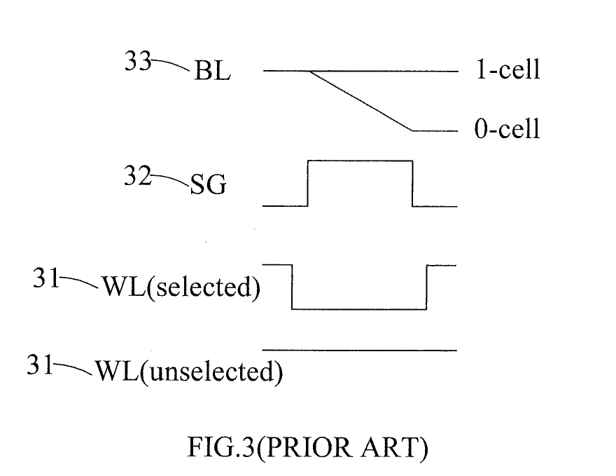

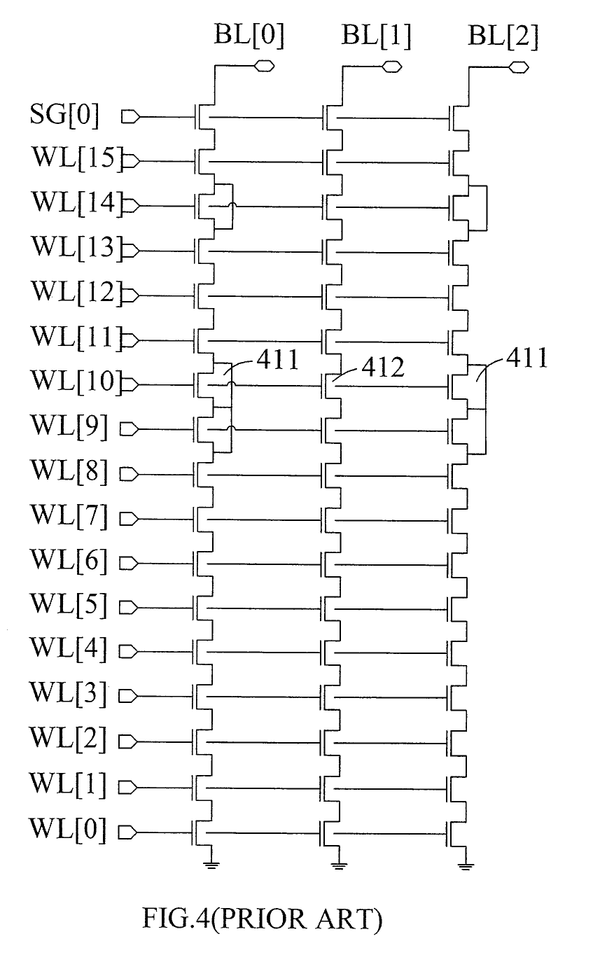

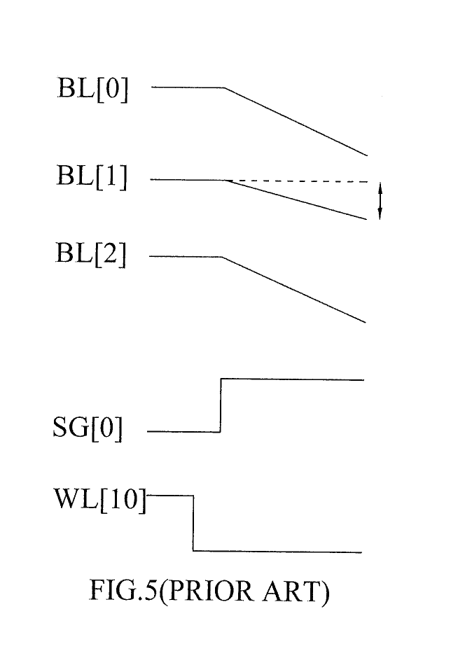

### DETAILED DESCRIPTION OF THE PREFERRED EMBODIMENTS

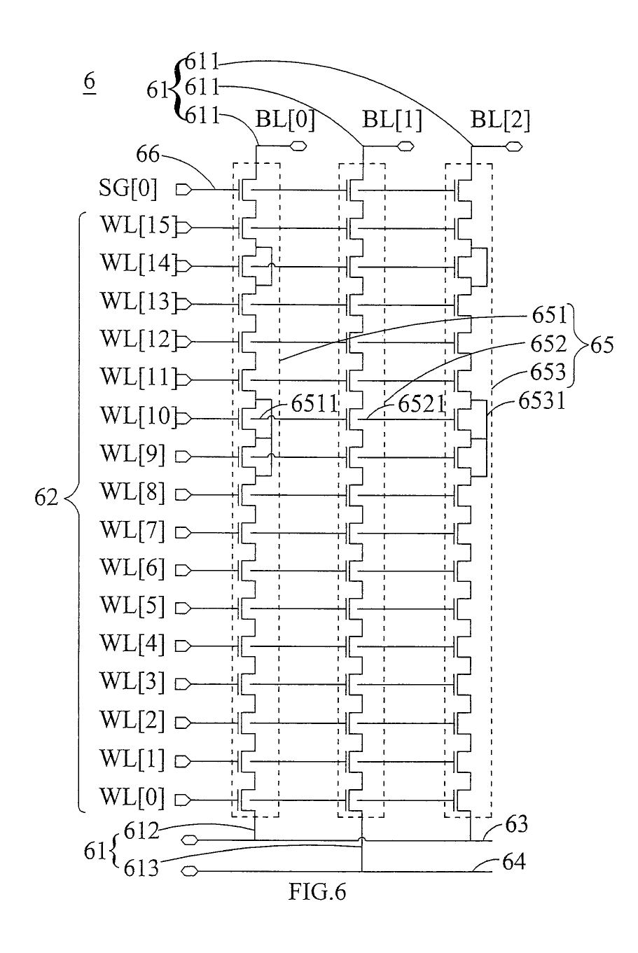

Referring to FIG. 6, in which a schematic view of a NAND type ROM of the present invention is shown. The NAND type ROM 6 comprises a plurality of bit lines 61, a plurality of word lines 62, a first source line 63, a second source line 64, and a plurality of NAND strings 65. The plurality of bit lines 61 comprise a plurality of upper bit lines 611, a plurality of first lower bit lines 612, and a plurality of second lower bit lines 613. The plurality of first lower bit lines 612 and the plurality of second lower bit lines 613 are alternately arranged in parallel, and the plurality of word lines 62 are vertically arranged to each bit lines 61. The first source line 63 is connected to the plurality of first lower bit lines 62. The second source line 64 is connected to the plurality of second lower bit lines 613. The plurality of NAND strings 65 comprise a plurality of first NAND strings 651 and a plurality of second NAND strings 652. The plurality of first NAND strings 651 are connected to the plurality of upper bit lines 611, the plurality of word lines 62, and the plurality of first lower bit lines 612. The plurality of second NAND strings 652 are connected to the plurality of upper bit lines 611, the plurality of word lines 62, and the plurality of second lower bit lines 613.

The NAND type ROM 6 further comprises a select gate (SG) line 66, and the plurality of NAND strings 65 are driven by the plurality of word lines 62 and the select gate line 66. Each NAND strings 65 may be formed by cascading a plurality of transistors. The gate of each transistors is electrically connected to each word lines 62.

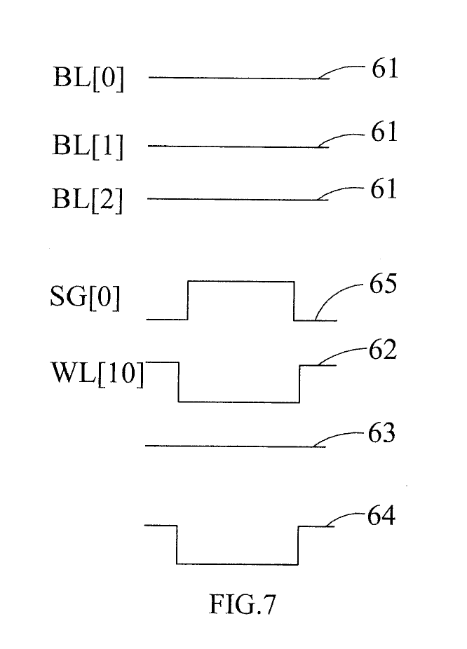

Referring to FIG. 7, in which an oscillogram of a NAND type ROM of the present invention is shown. Also referring to FIG. 6, when the logic state of the transistor 6511 of the first NAND string 651 is read by the bit line BL[0], the transistor 6511 is driven by the word line WL[10] and the select gate line SG[0]. The first source line 63 is set as a low-level operating voltage (i.e. V_{SS}) to read the logic state of the transistor 6511. The second source line 64 connected to the transistor 6521 of the second NAND string is maintained at a high-level operating voltage (i.e. V_{DD}). The crosstalk problem would be interdicted when a read memory cell is a 0-cell.

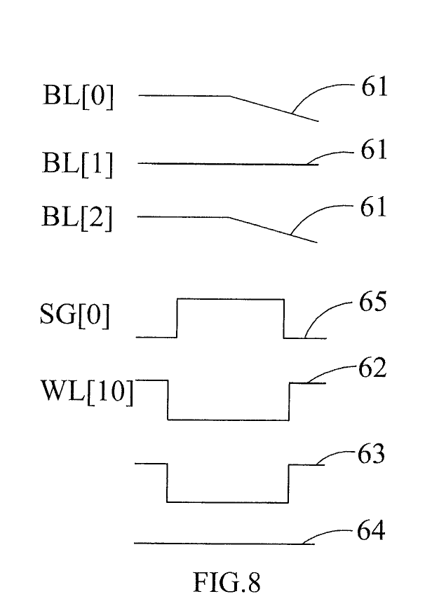

Referring to FIG. 8, in which an oscillogram of a NAND type ROM of the present invention is shown. Also referring to FIG. 6, when the transistor 6521 logic state of the second NAND string 652 is read by the bit line BL[1], the transistor 6521 is driven by the word line WL[10] and the select gate line SG[0]. The second source line 64 is set as a low-level operating voltage (i.e. V_{SS}) to read the logic state of the transistor 6521. The first source line 63 connected to the transistors 6511 and 6513 of the first NAND string is maintained at a high-level operating voltage (i.e. V_{DD}). When logic state of the transistor 6521 (1-cell) is read, it is expected that no voltage drop occurs at the bit line connected to the NAND string 652. Conventionally, the transistors 6511 and 6513 (0-cell) results in a voltage drop at the adjacent bit lines (BL[0] and BL[2]) connected to the NAND strings 651 and 653. Due to the crosstalk, an erroneous voltage drop may appear at the bit line where the transistor 6521 (1-cell) is disposed.

The present invention allows a read target (the transistor 6521) to be in a normal read operation via the first source line 63 and the second source line 64 alternatively arranged. The source lines of the adjacent non-read targets (the transistors 6511 and 6513) are at a high potential (V_{DD}) so that no voltage drop would occur at BL[0] and BL[2] whether a read memory cell is a 0-cell or a 1-cell. Therefore, erroneous voltage drops would not occur at the bit line (BL[1]) connected to the NAND string 652 where the read target (the transistor 6521) is disposed.

The above description is illustrative only and is not to be considered limiting. Various modifications or changes can be made without departing from the spirit and scope of the invention. All such equivalent modifications and changes shall be included within the scope of the appended claims.

What is claimed is:

1. A NAND type ROM comprising:
a plurality of bit lines comprising a plurality of upper bit lines, a plurality of first lower bit lines, and a plurality of second lower bit lines, the plurality of first lower bit lines and the plurality of second lower bit lines being alternately arranged in parallel;
a plurality of word lines being vertically arranged to each of the plurality of bit lines;
a first source line connected to the plurality of first lower bit lines;
a second source line connected to the plurality of second lower bit lines; and
a plurality of NAND strings comprising a plurality of first NAND strings and a plurality of second NAND strings, the plurality of first NAND strings being connected to the plurality of upper bit lines, the plurality of word lines, and the plurality of first lower bit lines, and the plurality of second NAND strings being connected to the plurality of upper bit lines, the plurality of word lines, and the plurality of second lower bit lines.

2. The NAND type ROM as claimed in claim 1, further comprising a select gate line, wherein the plurality of NAND strings are driven by the plurality of word lines and the select gate line.

3. The NAND type ROM as claimed in claim 1, wherein each of the plurality of NAND strings is formed by cascading a plurality of transistors.

4. The NAND type ROM as claimed in claim 3, wherein a gate of each of the transistors is electrically connected to each of the plurality of word lines.

5. The NAND type ROM as claimed in claim 1, wherein an operating voltage of the first source line is a low-level voltage and the operating voltage of the second source line is a high-level voltage when the plurality of first NAND strings are read.

6. The NAND type ROM as claimed in claim 1, wherein an operating voltage of the second source line is a low-level voltage and the operating voltage of the first source line is a high-level voltage when the plurality of second NAND strings are read.

7. The NAND type ROM as claimed in claim 1, wherein a crosstalk problem of the NAND type ROM is solved by the first source line and the second source line.

8. The NAND type ROM as claimed in claim 1, wherein no voltage drop caused by capacitance coupling occurs between the adjacent bit lines and read errors are reduced such that the NAND type ROM has full code-coverage and an increased reading speed.
